(19) United States
(12) Patent Application Publication
(10) Pub. No.: US 2021/0020541 A1
(43) Pub. Date: Jan. 21, 2021

(54) Thermal interface material having defined thermal, mechanical and electric properties

(71) Applicant: Infineon Technologies Austria AG, Villach (AT)

(72) Inventors: Christian KASZTELAN, Munchen (DE); Edward FUERGUT, Dasing (DE); Manfred MENGEL, Bad Abbach (DE); Fabio BRUCCHI, Villach (AT); Thomas BASLER, Riemerling (DE)

(21) Appl. No.: 17/062,614

(22) Filed: Oct. 4, 2020

Related U.S. Application Data
(62) Division of application No. 15/333,993, filed on Oct. 25, 2016.

(30) Foreign Application Priority Data
Oct. 26, 2015 (DE) 10 2015 118 245.9

(51) Int. Cl. H01L 23/373; H01L 23/36; H01L 23/495; C08K 3/22; C08K 3/28; C08K 3/34; C08K 3/38; C09K 5/14; H01L 21/48; H01L 21/56; H01L 23/31; H01L 23/367

(52) U.S. Cl. CPC H01L 23/3737; C08K 2003/385; H01L 23/49551; H01L 23/49575; C08K 3/22; C08K 3/28; C08K 3/34; C08K 3/38; C09K 5/14; H01L 21/4825; H01L 21/4882; H01L 21/565; H01L 23/3114; H01L 23/3677; H01L 23/49513; H01L 23/4952; H01L 23/49562; H01L 23/49568; H01L 23/49582; H01L 2224/48247; H01L 2924/181; H01L 2224/48139; H01L 2224/32245; H01L 23/3107; H01L 2224/73265; H01L 2224/4903; H01L 2224/48091; C08K 2003/2227; C08K 2003/2244; C08K 2003/282; H01L 23/36

(57) ABSTRACT

An electronic component comprising an electrically conductive carrier, an electronic chip on the carrier, an encapsulant encapsulating part of the carrier and the electronic chip, and an electrically insulating and thermally conductive interface structure, in particular covering an exposed surface portion of the carrier and a connected surface portion of the encapsulant, wherein the interface structure has a compressibility in a range between 1% and 20%, in particular in a range between 5% and 15%.

The present application is a continuation of U.S. patent application Ser. No. 15/33,993, filed Oct. 25, 2016, incorporated herein by reference in their entirety.

### BACKGROUND

### Technical Field

Various embodiments relate generally to electronic components, methods of manufacturing an electronic component, an arrangement, a thermal interface material, and methods of use.

### Description of the Related Art

A conventional electronic chip mounted on a chip carrier such as a leadframe, electrically connected by a bond wire extending from the chip to the chip carrier, and molded within a package may suffer from its thermal insulation within the package. Furthermore, such a conventional approach can reach its limits when complex electronic circuits shall be established.

For discrete Transistor Outline (TO) packages and other types of packages, the operation performance is limited in general by the amount of heat, which can be transferred to a cooling unit (such as a heat dissipation body) on board level. Therefore, thermal interface materials (TIM) are used as interface material between TO package (copper surface) and cooling unit. These materials may lack sufficient electrical isolation and are often not reliable in the way that during operation cycles their thermomechanical stability can be affected (so-called pump out effect). Furthermore, it may sometimes happen that dispensing of thermal grease is not properly performed leading to a possible thermal issue with the component. For example, an uneven dispensation of the thermal paste on a production line may be problematic.

As an alternative to the use of thermal grease, it is possible to use thermal interface material in form of an attachable foil. A disadvantage of such an approach is the high price and additional assembly effort in relation to the thermal conductivity performance, and a pronounced thermal contact resistance of the thermal interface material with regard to the chip carrier and the heat dissipation body.

One approach for overcoming such issues is the overmolding of the contact copper area. An advantage of overmolding the copper layer of the package is that apart from the increased reliability of the TIM layer also the thermal coupling to the copper layer is significantly increased and the thermal contact resistance between TIM material and the copper layer is reduced. This is accomplished by molding the TIM at high pressure and at increased temperature (for instance 150° C.) in a low viscous state to coat or wet the copper layer (in particular chip carrier and encapsulant) before being subsequently cured or hardened. Specific adhesion promoter in the mold compound and/or roughening the surface of the copper layer or increasing the micro roughness of the copper and/or adjacent component mold layer can additionally provide for an increased reliability and the reduction of the contact resistance. Here, a certain electrical isolation strength can be reached, but a compromise has to be made between performance and processability. The heat transfer performance is limited by the remaining mold thickness. For assembling to a cooling unit on board level, still a TIM material or thermal grease has to be used between heat sink and back-side of the package. Consequently, the same limitations as explained previously apply.

US 2014/0138803 discloses a chip arrangement including a carrier, a chip disposed over the carrier, the chip including one or more contact pads, wherein a first contact pad of the one or more contact pads is electrically contacted to the carrier, a first encapsulation material at least partially surrounding the chip, and a second encapsulation material at least partially surrounding the first encapsulation material.

### SUMMARY

There may be a need to provide a possibility to manufacture electronic chips with a simple processing architecture and with a high reliability.

According to an exemplary embodiment, an electronic component (such as a package) is provided which comprises an electrically conductive carrier, an electronic chip on the carrier, an encapsulant encapsulating part of the carrier and the electronic chip, and an electrically insulating and thermally conductive interface structure (for example covering an exposed surface portion of the carrier and a connected surface portion of the encapsulant, and for example being attached or to be attached at an external surface to a heat dissipation body), wherein the interface structure has a compressibility in a range between 1% and 20% (which may be measured by applying a 1 N force at a layer of the interface structure having a thickness of 250 μm using a Vickers-micro-indentor), in particular in a range between 5% and 15%.

According to another exemplary embodiment, an electronic component is provided which comprises an electrically conductive carrier, an electronic chip on the carrier, an encapsulant encapsulating part of the carrier and the electronic chip, and an electrically insulating and thermally conductive interface structure (for example covering an exposed surface portion of the carrier and a connected surface portion of the encapsulant, and for example to be attached at an external surface to a heat dissipation body), wherein the interface structure is made of a material having a silicone matrix filled with filler particles (for instance comprising or consisting of ZrO₂, Si₃N₄, BN, diamond, etc.), in particular metal oxide or metal nitride filler particles, with a mass percentage in a range between 75% and 98%, in particular in a range between 83% and 96%, more particularly in a range between 90% and 95%.

According to another exemplary embodiment, a method of manufacturing an electronic component is provided, wherein the method comprises mounting an electronic chip on an electrically conductive carrier, encapsulating part of the carrier and the electronic chip by an encapsulant, and forming (for instance encapsulating) an electrically insulating and thermally conductive interface structure (for instance to cover an exposed surface portion of the carrier and a connected surface portion of the encapsulant, and for example being attached or to be attached at an external surface to a heat dissipation body), wherein the interface structure has a compressibility (in particular relating to an elastic deformation) in a range between 1% and 20% (which may be measured by applying a 1 N force at a layer of the interface structure having a thickness of 250 μm using a Vickers-micro-indentor), in particular in a range between 5% and 15%.

According to another exemplary embodiment, a method of manufacturing an electronic component is provided, wherein the method comprises mounting an electronic chip on an electrically conductive carrier, encapsulating part of the carrier and the electronic chip by an encapsulant, and forming (for instance encapsulating) an electrically insulating and thermally conductive interface structure (for example to cover an exposed surface portion of the carrier and a connected surface portion of the encapsulant, and for example to be attached at an external surface to a heat dissipation body), wherein the interface structure is made of a material having a silicone matrix filled with filler particles (for instance comprising or consisting of ZrO₂, Si₃N₄, BN, diamond, etc.), in particular metal oxide and/or metal nitride filler particles, with a mass percentage in a range between 75% and 98%, in particular in a range between 90% and 95%.

According to yet another exemplary embodiment, an electronic component is provided which comprises an electrically conductive carrier which comprises a plurality of galvanically insulated separate carrier regions (in particular a plurality of carrier regions being provided separately from one another and being mutually spaced so as to form mutually galvanically insulated islands), a plurality of electronic chips each of which being mounted on a respective one of the carrier regions, an encapsulant encapsulating part of the carrier and the electronic chips, and a common electrically insulating and thermally conductive interface structure (in particular a continuous or an integral structure spatially extending beyond the multiple carrier regions and assigned electronic chips) covering an exposed surface portion of the carrier regions and a connected surface portion of the encapsulant.

According to yet another exemplary embodiment, a method of manufacturing an electronic component is provided, wherein the method comprises mounting each of a plurality of electronic chips on a respective one of a plurality of galvanically insulated separate carrier regions of an electrically conductive carrier, encapsulating part of the carrier and the electronic chips by an encapsulant, and forming a common electrically insulating and thermally conductive interface structure covering an exposed surface portion of the carrier regions and a connected surface portion of the encapsulant.

According to yet another exemplary embodiment, an arrangement is provided which comprises a mounting structure comprising an electric contact, and an electronic component having the above-mentioned features and mounted on the mounting structure so that the electronic chip is electrically connected to the electric contact.

According to still another exemplary embodiment, a heat dissipation body is provided which comprises a highly thermally conductive base body configured for dissipating heat, an electrically insulating and thermally conductive interface structure attached to the base body and to be attached to an exposed surface portion of a chip carrier of an electronic component, wherein the interface structure has a compressibility in a range between 1% and 20%, in particular in a range between 5% and 15%.

According to still another exemplary embodiment, a heat dissipation body is provided which comprises a highly thermally conductive base body configured for dissipating heat, an electrically insulating and thermally conductive interface structure attached to the base body and to be attached to an exposed surface portion of a chip carrier of an electronic component, wherein the interface structure is made of a material having a silicone matrix filled with filler particles (in particular filler particles comprising at least one of the group consisting of metal oxide, metal nitride, aluminum oxide, silicon oxide, boron nitride, zirconium oxide, silicon nitride, diamond, and aluminum nitride) with a mass percentage in a range between 75% and 98%, in particular in a range between 90% and 95%.

According to still another exemplary embodiment, an electrically insulating and thermally conductive interface material for integration with an electronic component is provided, wherein the interface structure has a compressibility in a range between 1% and 20% (which may be measured by applying a 1 N force at a layer of the interface structure having a thickness of 250 μm using a Vickers-micro-indentor), in particular in a range between 5% and 15%.

According to yet another exemplary embodiment, an interface material having the above-mentioned features is used for providing an electric isolation and a thermal coupling between a chip carrier of a package or electronic component and a heat dissipation body or cooling unit.

According to yet another exemplary embodiment, an electrically insulating and thermally conductive interface material for integration with an electronic component, wherein the interface material is made of a material having a silicone matrix filled with filler particles (for instance comprising or consisting of ZrO₂, Si₃N₄, BN, diamond, etc.), in particular metal oxide and/or metal nitride filler particles, with a mass percentage in a range between 75% and 98% (in particular in a range between 90% and 95%), is used for providing an electric isolation and a thermal coupling between a chip carrier of the electronic component and a heat dissipation body.

According to an exemplary embodiment of the invention, a thermal interface material with advantageously adjusted electric, mechanical and thermal properties is provided. Such an interface material may be arranged at a thermal and electric interface between a chip carrier (such as a leadframe) and an encapsulant (such as a mold compound) on the one hand and a heat sink (such as a heat dissipation body) on the other hand. Firstly, the provided interface material has appropriate mechanical properties for providing a sufficiently soft transition between package and heat dissipation body to thereby promote a proper heat removal during operation. Secondly, the provided interface material has sophisticated properties in terms of electric insulation to thereby reliably prevent any undesired flow of electricity between an interior of the package and an exterior of the package. This is in particular of utmost importance for power semiconductor applications. Thirdly, its thermal properties are adjusted in a desirable way so as to provide a high contribution in terms of heat removal during operation. Such a concept is applicable for a single layer or a multi-layer architecture, a combination of soft and hard layers, etc.

In particular when the interface structure has a compressibility (in particular under adiabatic or under isothermal conditions) within the above defined ranges, a sufficiently soft and sufficiently stable interface structure is obtained which has the mechanical softness of filling gaps to improve thermal coupling and provides the mechanical rigidity for reliably ensuring electric insulation even in the presence of scratch or delamination forces. For the given compressibility ranges, a desired high softness is obtained. As a consequence of this softness, the thermal interface material is capable of filling substantially any microgaps at a surface of a heat dissipation body, thereby improving the external thermal coupling. When the thermal interface material on the package is therefore pressed against the heat dissipation body, no or at least no major thermal gaps in form of microscopic air volumes occur. On the other hand, a too soft property is avoided which might have an undesired impact on the electrical reliability and a delamination danger of the thermal interface material. At the same time, a robust (in terms of handling and mounting) and scratch resistant solution is provided. With appropriate compressibility values, it can be achieved that the material of the thermal interface structure properly adapts itself to the material of the heat sink.

The above-mentioned technical advantages may be in particular obtained by configuring the thermal interface material from a soft silicone matrix in which a sufficiently large amount of properly thermally conductive and electrically insulating filler particles (for instance of metal oxide and/or metal nitride, in particular of at least one of the group consisting of ZrO₂, Si₃N₄, BN, diamond, etc.) are embedded.

Advantageously, a single common thermal interface structure (for instance a common thermal interface layer) may cover a plurality of mutually galvanically insulated carrier regions, wherein each of the carrier regions carries a respective one of multiple electronic chips. This allows to process the multiple commonly encapsulated electronic chips on the mutually electrically decoupled chip carrier regions altogether on the backside of the package or electronic component in terms of formation of a common thermal interface structure. More specifically, forming the thermal interface structure for the multiple chip carrier regions may be performed in one single common procedure, and thus very efficiently.

As an alternative to the attachment of the thermal interface structure with the described advantageous characteristics onto a carrier (and optionally additionally onto an encapsulant) of an electronic component, which is to be attached, in turn, to a heat dissipation body, it is also possible to firmly attach the interface structure onto a heat dissipation body. Such a heat dissipation body with the attached thermal interface structure thereon may then be attached onto an exposed surface portion of a carrier of an electronic component which itself does not have a thermal interface structure on the exposed surface of its carrier.

### DESCRIPTION OF FURTHER EXEMPLARY EMBODIMENTS

In the following, further exemplary embodiments of the electronic component, the method of manufacturing an electronic component, the arrangement, the thermal interface material, and the method of use will be explained.

Compressibility β may be defined as a measure of the relative volume (V) change (δV/δp) of the solid thermal interface material as a response to a pressure p (or mean stress) change, more precisely as −(δV/δp)/V. The given compressibility values may refer to a temperature of 20° C. and/or of 150° C., 175° C. or 250° C., etc.

In an embodiment, the interface structure has (in particular at a temperature of 20° C.) a value of the breakdown voltage per thickness (in particular of a layer-type interface structure) multiplied with the thermal conductivity divided by the square of the Vickers hardness of more than 1 kV W mm³ m⁻¹ K⁻¹ N⁻², in particular more than 3 kV W mm³ m⁻¹ K⁻¹ N⁻², more particularly of more than 10 kV W mm³ m⁻¹ K⁻¹ N⁻². It has turned out that, for simultaneously meeting all criteria of a highly appropriate thermal interface material in terms of thermal, mechanical and electrical performance, thermal conductivity multiplied with electrical breakdown voltage per thickness divided by the square of the Vickers hardness is a highly appropriate parameter. If this parameter assumes a sufficiently large value of at least 1 kV W mm³ m⁻¹ K⁻¹ N⁻², preferably of at least 3 kV W mm³ m⁻¹ K⁻¹ N⁻², a proper trade-off between all above mentioned boundary conditions in terms of thermomechanical and electromechanical behaviour is obtained.

In the context of the present application, the term “Vickers hardness” may particularly denote a standardized microhardness of the material of the thermal interface structure. For this purpose, an indenter in form of a pyramid-shaped diamond body may be pressed with a defined force against a surface of the thermal interface material and the resulting protrusion depth is measured. For measuring the Vickers hardness, the indenter may be embodied as a diamond in the form of a square-based pyramid which results in an indenter shape being capable of producing geometrically similar impressions irrespective of size, in an impression which has well-defined points of measurement, and in an indenter which has high resistance to self-deformation. The Vickers hardness (HV number) can then be determined by the ratio F/A, wherein F is the force applied to the diamond and A is the surface area of the resulting indentation.

In the context of the present application, the term “electric breakdown voltage” may particularly denote a value of an electric voltage applied to the thermal interface material which voltage, when reached or exceeded, results in an electrical breakdown or dielectric breakdown of the thermal interface material. Such an electric breakdown corresponds to a rapid reduction in the resistance of the (previously electrically insulating) interface material when the voltage applied across it exceeds the breakdown voltage. This results in at least a portion of the thermal interface material becoming electrically conductive. The electrical breakdown voltage of the thermal interface material may refer to an alternating current (AC) peak voltage measurement at a standard frequency (of in particular 50 Hz). Breakdown voltage may be given per thickness of a layer of the interface material.

In an embodiment, electric breakdown voltage of the material of the thermal interface structure may be measured by applying an alternating current (AC) to the thermal interface material with a frequency of 50 Hz and to measure the border voltage at or above which the thermal interface material transits from an electrically insulating behaviour to an electrically conductive behaviour, i.e. starts to transmit an electric current when applying the electric voltage. A given value of the electrical breakdown voltage may correspond to an AC peak voltage at a frequency of 50 Hz.

In the context of the present application, the term “thermal conductivity” may particularly denote a capability of the material of the interface structure itself defining how much thermal energy can be conducted or removed via the thermal interface material per distance and per temperature difference between a source and a drain of the thermal energy.

In an embodiment, thermal conductivity of the material of the thermal interface structure may be measured by placing a sample of thermal interface material between two plates of known thermal conductivity (for example brass plates). The setup may be vertical with a hotter one of the plates at the top, the sample in between and the colder one of the plates at the bottom. Heat is supplied at the top and made to move downwards to stop any convection within the sample. Measurements may be taken after the sample has reached to a steady state (with zero heat gradient or constant heat over entire sample).

Also laser flash analysis may be used to measure thermal diffusivity of one or a multiplicity of different materials. An energy pulse heats one side of a (for instance plane-parallel) sample. The temperature rise on the backside due to the energy input is time-dependent detected. The higher the thermal diffusivity of the sample, the faster the energy reaches the backside. The thermal diffusivity is also a measure for thermal conductivity or thermal resistivity.

In an embodiment, the interface structure has a Vickers hardness in a range between 0.50 N/mm² and 3 N/mm², in particular in a range between 0.85 N/mm² and 1.50 N/mm², at a measuring force of 1 N. It has turned out that in the mentioned range of values of the Vickers hardness, the material is at the same time sufficiently soft to have the capability of filling out microprotrusions of the heat dissipation body to be attached, and is sufficiently robust to prevent the formation of scratches and mechanical damage of the thermal interface material itself during handling and use. When configuring the thermal interface structure with a soft characteristic, a good adhesion to the carrier (such as a leadframe) and to the encapsulant may be achieved, and additionally a filling of roughnesses on a heat sink surface may be accomplished at the same time.

In an embodiment, the interface structure has a maximum indention depth of a Vickers indentor at a measuring force of 1 N of less than 100 μm, in particular at a measuring force of 1 N of less than 50 μm. When the present condition in terms of indentation depth is met, already quite thin thicknesses of the thermal interface material are sufficient to ensure the required mechanical integrity under typical mechanical impacts and loads during handling and operation. Then, a sufficiently high mechanical integrity may be combined with a proper thermal coupling between an interior of the package and an exterior of the package via the thermal interface material (which thermal coupling is better for a thinner thermal interface material).

In an embodiment, the interface structure has a Young modulus (in particular at a temperature of 20° C.) in a range between 0.1 GPa and 2 GPa, in particular between 0.3 GPa and 1.5 GPa, more particularly in a range between 0.5 GPa and 1.0 GPa. The Young modulus, also denoted as the tensile modulus, is a mechanical property of linear elastic solid materials and indicates the force (per unit area) that is needed to stretch (or compress) a material sample. In the given range of values of the Young modulus, the thermal interface material is sufficiently soft for providing for a smooth and gap-free contact with a heat dissipation body. However, compressibility of the thermal interface material is not exaggerated in this range which maintains the desired electrical and mechanical properties during operation.

In an embodiment, the interface structure has a creeping (i.e. a plastic deformation) at a measuring force of 1 N in a range between 4% and 7%, in particular in a range between 4.8 GPa and 6.4 GPa.

In an embodiment, the interface structure shows a scratch resistance at a measuring force of 1 N (using a diamond indenter with radius of curvature of 220 μm and cone angle of 120°) without effect on the electrical breakdown specification of at least 5.6 kV. In particular, no negative impact in the BDV class, for example 2.5 kV, 2 kV (or lower voltage class or higher voltage class) occurs in one embodiment. In other words, the interface material may be configured sufficiently hard that a scratch formation test (simulating mechanical loads under harsh use conditions) does not result in the generation of scratches which reduce the electrical breakdown voltage below 5.6 kV. The mentioned value of 5.6 kV refers to an AC peak voltage measurement at 50 Hz (for instance at a thermal interface material thickness of for example 250 μm or lower or higher). Additionally or alternatively, the interface structure shows a scratch resistance at a measuring force of 1 N (using a diamond indenter with radius of curvature of 220 μm and cone angle of 120°) without effect on an electrical breakdown voltage per thickness (of a layer of the thermal interface structure) of at least 10 kV/mm. For measuring the scratch resistance, an indenter (in particular having a pyramid shape and made of diamond material) may be vertically pressed with a certain force (in particular 1 N) exerted on a surface of the thermal interface material and may be moved with this mechanical load along the surface of the thermal interface material. Such a scratch test may be defined to be passed by the thermal interface material when the thermal interface material having undergone the scratch test still has a value of the electric breakdown voltage of at least 5.6 kV (or still has an electrical breakdown voltage per thickness of at least 10 kV/mm). The given values of the electrical breakdown specification may refer to typical thicknesses of the thermal interface material (typically in the order of magnitude of hundreds micrometers). Particularly appropriate ranges of breakdown voltage values per thickness are between 10 kV/mm and 20 kV/mm, in particular between 15 kV/mm and 20 kV/mm.

By integrating the thermal interface structure in the package rather than attaching an external foil to the package, a better heat transfer can be obtained, because one thermal boundary (i.e. in an interior of the package) can be omitted.

In an embodiment, the interface structure has a thickness in a range between 50 μm and 600 μm, in particular in a range 100 μm and 400 μm. For example, the interface structure may be a planar layer with a thickness of more than 150 μm, in particular of more than 200 μm, more particularly in a range between 70 μm and 300 μm. For example, the thickness may be 250 μm. Sufficiently high thicknesses of the thermal interface material allow for a reliable dielectric or electrically insulating separation between the carrier in an interior of the package and an exterior thereof. However, the thicker the thermal interface material, the stronger will the thermal energy removal capability of the thermal interface structure be influenced. The given range allows to obtain both proper thermal conditions and electrical conditions at the same time. Also a scratch resistance may be ensured with the mentioned thicknesses even under harsh conditions.

In an embodiment, the interface structure has an electric breakdown voltage (AC root mean square value) of at least 2 kV, in particular of at least 5 kV more particular in a range between 5 kV and 12 kV. Additionally or alternatively, the interface structure may have an electric breakdown voltage (AC root mean square value) per thickness (of a layer of the thermal interface structure) of at least 5 kV/mm, in particular of at least 10 kV/mm, more particularly of at least 15 kV/mm. A corresponding specification also meets the demands of high power applications. In particular, a correspondingly configured package is suitable for power applications as occur in the automotive field.

In an embodiment, the interface structure has a comparative tracking index of at least 400, in particular at least 600 (or even higher).

In an embodiment, the interface structure has a thermal conductivity of at least 1 W m⁻¹ K⁻¹, in particular of at least 2 W m⁻¹ K-1 or, more particularly in a range between 3 W m⁻¹ K⁻¹ and 20 W m⁻¹ K⁻¹. The thermal interface material shall be properly electrically insulating and thermally conductive at the same time. To obtain this, the physical boundary conditions are challenging. However, it has turned out that the mentioned values of thermal conductivity are on the one hand higher than those of typical encapsulants (such as a mold compound) so that the thermal interface material efficiently removes heat from the package, and also allow to provide the thermal interface material with sufficient dielectric properties.

In an embodiment, the interface structure consists of a single layer. Therefore, it is dispensable to provide complex layer stacks of multiple layers for meeting the various thermomechanical and electrical properties at the same time. A single layer has turned out to be sufficient. This also reduces the effort for forming the thermal interface structure.

In an embodiment, the interface structure comprises or consists of a soft matrix (for instance a polymer matrix) filled with filler particles. Generally, it is a challenge to meet the above-mentioned electrical, mechanical and thermal requirements at the same time. However, with the combination of a matrix providing sufficient softness and filler particles providing sufficient electrical insulation and thermal conductivity, all conditions may be met at the same time.

In an embodiment, the matrix comprises or consists of silicone. Silicone is highly appropriate as a matrix material for the thermal interface structure, since it has mechanically soft properties and is compatible with the embedding of filler particles therein. Alternatively, the polymer matrix may comprise or consist of an epoxy material. It is also possible to configure the matrix from a polymer mixture of silicone and epoxy material. Furthermore, it is possible to use polyimide and/or polyacrylate and/or cyanate ester and/or BMI (Bis-Maleimides) as matrix material. In an advantageous embodiment, a thermoplastic material may be used as matrix material. Such a thermoplast may provide a high softness in particular at high temperatures allowing the interface material to adjust itself to a contact surface in particular at high temperature values. The various materials mentioned as examples for the matrix may also be combined to form a multi material matrix.

In an embodiment, the filler particles comprise or consist of at least one of the group consisting of aluminum oxide, silicon oxide, boron nitride, zirconium oxide, silicon nitride, diamond and aluminum nitride. Any kind of mixture or combination between these and other filler particles is possible. With the mentioned materials for the filler particles, for instance microscopic spheres or beads, in particular thermal conductivity and dielectric behaviour may be promoted. Optionally, it is possible to include one or more further additives as or to the filler particles. Examples are silicone particles, silicone oil, thermoplastic material particles, carbon black, etc. Such additives may be added to adjust one or more physical parameters, for instance to reduce the Young modulus. Moreover, it is possible to adjust to the surface properties of the filler particles (for instance by coating, for example with a silane coating to improve adhesion which, in turn, has a positive impact on the capability of removing heat). By such a surface treatment, one or more physical properties of the interface material may be tuned (such as moisture protection, adhesion promotion, improvement of the thermal conductivity, etc.).

In an embodiment, a mass percentage of the filler particles is at least 80%, in particular at least 90%. Thus, it has turned out that already very small percentages of matrix material, for instance silicone or epoxy-based materials, are sufficient to provide the desired softness. The large majority of the thermal interface material may therefore be formed by the filler particles by which the various requirements in terms of thermal, electrical and mechanical properties can be freely adjusted.

In an embodiment, the thermal interface structure is made of a material which is a ceramic compound, for instance aluminium oxide particles in a silicone grid.

When the thermal interface structure is composed as a mixture of silicone and filler particles, it may have, as such, a white color. However, it may be advantageous to color the thermal interface structure (for instance by carbon black particles) in order to promote heat radiation capabilities, which further improves the thermal behaviour.

In an embodiment, a parasitic capacitance constituted by the interface structure in combination with the carrier and a heat dissipation body to be attached to an external surface of the interface structure has a capacitance in a range between 10 pF and 100 pF, in particular in a range between 25 pF and 55 pF. The mentioned capacitance values obtained when selecting the combination of electrical breakdown voltage, thermal conductivity and Vickers hardness, is sufficiently small to still render the thermal interface material suitable even for high power and/or high frequency applications. The carrier and a metallic heat sink separated by the dielectric thermal interface material form a parasitic capacitance. This parasitic capacitance may result in losses during operation. However, the given capacitance values typical for the above set of thermal, electrical and mechanical parameters, refer to an acceptable range even for high frequency applications.

In an embodiment, the mounting structure comprises a printed circuit board. However, other mounting structures are possible as well.

In an embodiment, the electronic component is configured as one the group consisting of a leadframe connected power module, a Transistor Outline (TO) electronic component, a Quad Flat No Leads Package (QFN) electronic component, a Small Outline (SO) electronic component, a Small Outline Transistor (SOT) electronic component, and a Thin Small Outline Package (TSOP) electronic component. Therefore, the electronic component according to an exemplary embodiment is fully compatible with standard packaging concepts (in particular fully compatible with standard TO packaging concepts) and appears externally as a conventional electronic component, which is highly user-convenient. In an embodiment, the electronic component is configured as power module, for instance molded power module. For instance, an exemplary embodiment of the electronic component may be an intelligent power module (IPM). Another exemplary embodiment of the electronic component is a dual inline package (dip).

In an embodiment, the interface structure, the covered exposed surface portion of the carrier and the connected surface portion of the encapsulant are integrally formed with one another, in particular so that the interface structure is not detachable from a remainder of the electronic component. In the described embodiment, the thermal interface structure is not configured as a foil or any other separate member to be merely attached from an exterior to the encapsulant onto the exposed surface of the carrier, but in contrast to this, carrier, encapsulant and thermal interface structure may form an integral structure altogether. Thus, any delamination is safely prevented. Furthermore, a user does not have to attach a foil manually to the package, but in contrast to this, a ready-to-use or plug-and-play module is provided. This significantly simplifies handling of the package at a user side. By the integral formation of the thermal interface structure with the package, the thermal resistivity between the thermal interface material and the package can be advantageously reduced.

In an embodiment, material of the interface structure is intermingled with material of the covered exposed surface portion of the carrier and/or material of the connected surface portion of the encapsulant. The integral character of carrier, encapsulant and thermal interface structure can further be promoted by manufacturing the package so that during the manufacture, material flows mutually between the mentioned components of the package. By such a material exchange, the danger of interior heat gaps and electric creeping current paths in an interior of the package can be further reduced.

In an embodiment, the interface structure extends over an entire main surface of the encapsulant and over the entire exposed surface portion of the carrier at a main surface of the electronic component. In other words, one entire main surface of the package may be coated with the thermal interface material. This can be a result of the manufacturing procedure of the thermal interface material which is preferably not based on the attachment of a thermal interface foil to the package, but in contrast to this, an integral formation of the thermal interface material by molding or lamination is performed. Furthermore, such a full coating of one entire surface of the package with a thermal interface structure further improves the mechanical robustness and the suppression of the danger of undesired creeping currents between an interior and an exterior of the package. Thus, it is advantageous according to an exemplary embodiment of the invention that the size of the thermal interface structure fits exactly to a size of the package. Preferably, the outline of the thermal interface structure and of one main surface of the package are identical. However, since a clamping area requires a certain space, the thermal interface layer may be also smaller than the package area in a fan-in structure.

In an embodiment, the interface structure has a relative permittivity εᵣ in a range between 1.5 and 6, in particular in a range between 4 and 5. Such small values of the relative dielectric constant are advantageous in terms of suppressing electric losses due to parasitic capacitances formed between thermal interface structure (as dielectric) and heat dissipation body/carrier (as capacitance plates).

In an embodiment, the carrier comprises a plurality of galvanically insulated separate carrier regions. It is for example possible that a separate electronic chip is mounted on each of the separate carrier regions. Thus, even complicated electronic tasks may be accomplished. The galvanically insulated separate carrier regions may be separated from one another by electrically insulating material of an encapsulant. They may be electrically connected to one another, if desired, by a bond wire or the like. In one embodiment, each carrier region may have a different voltage potential, for instance up to 6.5 kV.

In an embodiment, the carrier comprises a plurality of sections of different thickness. This increases the design flexibility in terms of electrical and mechanical properties of different sections of the carrier. Alternatively, it is possible that the carrier has a homogeneous thickness over its entire extension.

In an embodiment, the interface structure is formed (in particular encapsulated) by at least one of the group consisting of molding, in particular compression molding or transfer molding, stencil printing, and laminating. Thus, such manufacturing methods may promote the formation of an integral thermal interface which may also intermingle with carrier and/or encapsulant. It is alternatively possible to manufacture the interface structure with a generative or an additive (for instance software controlled) manufacturing procedure such as printing, in particular three-dimensional printing. The mentioned manufacturing procedures are therefore preferred over the attachment of a thermal interface foil on the remainder of the package. By molding or laminating, the thermal interface structure may be connected to the remainder of the package by the application of pressure and heat, optionally under vacuum, preferably accompanied by a curing reaction.

In an embodiment, the interface structure is connected to the exposed surface portion of the carrier and to the connected surface portion of the encapsulant by chemically modifying the material of the interface structure, in particular by at least one of the group consisting of cross-linking and melting or any chemical reaction. The integral character of thermal interface material with carrier and/or encapsulant may be further promoted by a chemical reaction initiating the formation of the thermal interface structure.

The thermal interface structure according to an exemplary embodiment of the invention is easy to use and provides a plug-and-play package, since no further material (such as unreliable thermal grease and/or paste) is required between the package and the heat sink. Since the handling of thermal grease is dispensable according to exemplary embodiments of the invention, there remains no danger that a customer unintentionally influences performance of the electronic device by an unskilled handling of the thermally grease.

Softness of the thermal interface structure provides for a reliable contact to the heat sink, since the thermal interface material then has the capability of penetrating into microholes or microgrooves or other kind of micro roughness of the heat sink. Silicone as a constituent of the thermal interface structure is particularly advantageous in this respect. Moreover, a certain softness of the thermal interface material compensates potential bending of the package, for instance in the presence of thermal load. When however the softness of the thermal interface structure becomes too pronounced, undesired scratches may occur during handling and operation of the package which may involve the danger of voltage breakdown.

Advantageously, the thermal interface material may be temperature-resistant in the full operational range of packages, in particular between −60° C. and 175° C. In this context, silicone is particularly appropriate as constituent of the thermal interface material. Furthermore, silicone material may have a high permanent use temperature of at least 200° C. or even up to 250° C. or more.

In an embodiment, a through hole extends at least through the encapsulant and the interface structure so that a fastening element (such as a screw or a bolt) is guidable through the through hole for fastening the electronic component to a heat dissipation body. In an embodiment, the fastening element may form part of the electronic component. Mounting the electronic component to the heat dissipation body by a fastening element such as a screw is simple and cheap.

In an embodiment, the electronic component comprises a clip configured for connecting the electronic component to a heat dissipation body. Such a clip may be configured to clamp the encapsulated chip-carrier arrangement with thermal interface coating against the heat dissipation body without the need to form a through hole. Although the effort for connecting a heat dissipation body to the rest of the electronic component by a clip is somewhat higher than by a fastening element such as screw, it is nevertheless advantageous in particular for high-performance applications.

As an alternative to a screw or clip connection, other fastening techniques may be applied (such as another clamping technique).

Thermal conductivity of the material of the interface structure may be higher than thermal conductivity of the material of the encapsulant. For instance, thermal conductivity of the material of the encapsulant may be in a range between 0.8 W m⁻¹ K⁻¹ and 8 W m⁻¹ K⁻¹, in particular in a range between 2 W m⁻¹ K⁻¹ and 4 W m⁻¹ K⁻¹. For example, the material of the interface structure may be a silicone-based material (or may be made on the basis of any other resin-based material, and/or combinations thereof) which may comprise filler particles for improving thermal conductivity. For example, such filler particles may comprise or consist of aluminum oxide (and/or boron nitride, aluminum nitride, diamond, silicon nitride). For materials comprising or consisting of zirconium oxide, boron nitride, silicon nitride, diamond, etc., values of 15 W m⁻¹ K⁻¹ may be obtained, possibly values in a range between 20 W m⁻¹ K⁻¹ and 30 W m⁻¹ K⁻¹.

In an embodiment, the carrier comprises or consists of a leadframe. A leadframe may be a metal structure inside a chip package that is configured for carrying signals from the electronic chip to the outside, and/or vice versa. The electronic chip inside the package or electronic component may be attached to the leadframe, and then bond wires may be provided for attach pads of the electronic chip to leads of the leadframe. Subsequently, the leadframe may be moulded in a plastic case or any other encapsulant. Outside of the leadframe, a corresponding portion of the leadframe may be cut-off, thereby separating the respective leads. Before such a cut-off, other procedures such a plating, final testing, packing, etc. may be carried out, as known by those skilled in the art. Leadframe or chip carrier can be coated before encapsulation, for instance by an adhesion promoter.

In an embodiment, the electronic component further comprises the above-mentioned heat dissipation body attached or to be attached to the interface structure for dissipating heat generated by the electronic chip during operation of the electronic component. For example, the heat dissipation body may be a plate of a properly thermally conductive body, such as copper or aluminium or graphite, diamond, composite material and/or combinations of the mentioned and/or other materials, which may have cooling fins or the like to further promote dissipation of heat which can be thermally conducted from the electronic chip via the chip carrier and the interface structure to the heat dissipation body. The removal of the heat via the heat dissipation body may further be promoted by a cooling fluid such as air or water (more generally a gas and/or a liquid) which may flow along the heat dissipation body externally of the electronic component. Also heat pipes may be implemented.

In an embodiment, the electronic component is adapted for double-sided cooling. For example, a first interface structure may thermally couple the encapsulated chip and carrier with a first heat dissipation body, whereas a second interface structure may thermally couple the encapsulated chip and carrier with a second heat dissipation body.

In an embodiment, the electronic chip is configured as a power semiconductor chip. Thus, the electronic chip (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the electronic chip experiences a vertical current flow. The package architecture according to exemplary embodiments of the invention is particularly appropriate for high power applications in which a vertical current flow is desired, i.e. a current flow in a direction perpendicular to the two opposing main surfaces of the electronic chip, one of which being used for mounting the electronic chip on the carrier.

As substrate or wafer forming the basis of the electronic chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

For the encapsulating, a plastic material or a ceramic material may be used.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

In one embodiment, one or more of the various given parameter values (in particular compressibility, Young modulus, Vickers hardness, thermal conductivity, breakdown voltage, breakdown voltage per thickness, MAME, etc.) of the thermal interface material hold for an ambient temperature of for example 25° C. or 20° C. (or room temperature). Additionally or alternatively, one or more of the various given parameter values (in particular compressibility, Young modulus, Vickers hardness, thermal conductivity, breakdown voltage, breakdown voltage per thickness, MAME, etc.) of the thermal interface material may hold for an operation temperature of for example 175° C. and/or 200° C. and/or 250° C.

The above and other objects, features and advantages will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of an electronic component according to an exemplary embodiment of the invention, to be mounted on a mounting structure for establishing an arrangement according to an exemplary embodiment of the invention.

FIG. 2 illustrates a diagram illustrating a dependence of Vickers hardness from a product of thermal conductivity and breakdown voltage per thickness of a material of an interface structure of an electronic component according to an exemplary embodiment of the invention.

FIG. 3 illustrates an SEM image of aluminum oxide filled silicone as material for an interface structure of an electronic component having a conductive carrier according to an exemplary embodiment of the invention.

FIG. 4 illustrates different views of electronic components according to exemplary embodiments of the invention.

FIG. 5 illustrates a plan view of an electronic component according to an exemplary embodiment of the invention having multiple galvanically insulated separate carrier regions.

FIG. 6 illustrates a plan view of an electronic component according to another exemplary embodiment of the invention having multiple galvanically insulated separate carrier regions.

FIG. 7 illustrates a plan view of an electronic component according to yet another exemplary embodiment of the invention having multiple separate carrier regions.

FIG. 8 illustrates a circuit diagram illustrating the electronic functionality of the electronic component according to FIG. 7.

FIG. 9 illustrates a cross-sectional view of an electronic component according to an exemplary embodiment of the invention having a carrier with multiple different sections of different thickness.

FIG. 10 illustrates a cross-sectional view of an electronic component according to an exemplary embodiment of the invention having multiple galvanically insulated separate carrier regions connected to one another by a bond wire.

### DETAILED DESCRIPTION

The illustration in the drawing is schematically and not to scale.

Before exemplary embodiments will be described in more detail referring to the figures, some general considerations will be summarized based on which exemplary embodiments have been developed.

An exemplary embodiment provides an electronic component or package configured as a discrete device with specifically adapted thermal interface contact(s). More specifically, a coating material may be placed as thermal interface structure on an exposed metal (in particular copper) surface of the package (in particular a TO-package) with a defined softness of the layer. Thus, it is possible to assemble the thermal interface structure as a one-layer substrate having a high electrical isolation and at the same time low stiffness for efficiently promoting surface wetting of a mounted heat dissipation body such as a cooling unit. The electrical, thermal and mechanical properties (for instance stiffness) of the thermal interface structure can be specifically matched so as to obtain one, some or all of the following technical advantages:
A reduced effort for providing the thermal interface material may be achieved, and easier processing at customer location may be enabled. By attaching a TIM layer to the package, the package can be used in a plug and play mode, without the need to apply an additional isolation or contact medium. In this context, a sufficient softness of the TIM is advantageous, as well as a sufficient compressibility in order to balance out an uneven surface.
An improved reliability may be obtained, since no local movement of paste materials at mounted status especially at operation cycles occurs. A constant pressure (i.e. pressing-on-the-workpiece pressure exerted during mounting, for instance during screwing or clipping, the package or electronic component onto the heat dissipation body) and a constant layer thickness are possible.
An improvement of the thermal performance is possible with a molded thermal interface material according to an exemplary embodiment of the invention compared to thermal grease and also compared to conventional thermal interface foils due to the reduced thermal contact resistance between the interface material and the chip carrier, in particular when specially filled polymers are used.
A manufacturer may deliver the total electronic component as a system solution without any danger that performance of the electronic component may be decreased by the use of low-grade grease or the like by an end user.
Especially for applications like solar cells, inductive heating, inductive welding, UPS, etc. with continuous operation and reduced leadframe thickness (single gauge), a package with thermal interface material according to an exemplary embodiment of the invention may be used in a cost efficient and reliable way.
Certain application designs, so-called single end topologies, may benefit from a decoupling of the package backside (drain) from the cooling unit (for instance a heat sink made of aluminum). This may reduce noise levels for the complete electronic circuits (close to the heat sink). Disturbances originating from rapid voltage jumps at the heat sink can lead to higher EMR (electromagnetic radiation), for instance trigger undesired gate-on signals (which may result in an undesired destruction of the gate driver).

Exemplary embodiments of the invention may enable the delivery of TO-packages without the need of conventional TIM or grease for mounting the package on a cooling unit by an assembly of the thermal interface layer on the package at the copper surface of the carrier. Such a thermal interface layer or layer system according to an exemplary embodiment of the invention may combine at least part of the following properties:
Thickness: between 70 μm and 300 μm (for example 250 μm)
Polymer matrix: silicone
Type of filler of thermal interface layer: Al₂O₃, SiO₂, BN, AlN with a filling degree of between 90 mass % and 95 mass %
Thermal conductivity: 2 W/mK to 15 W/mK (which may for instance be measured by laser flash analysis)
Electrical isolation capability: for a thickness of 200 μm, the electrical breakdown AC peak voltage may be at least 2.5 kV (for instance at a thickness of 250 μm), in particular at least 8 kV. By varying the thickness of the thermal interface layer and the content of filler particles as design parameters, it is possible to cover at least a range between 5.6 kV and 12 kV.
Vickers hardness (HV) may be at or below 3 N/mm², preferably within a range of ±20% around 1 N/mm². This corresponds to a value of the Young modulus of ±20% around 0.6 GPa.
With the characterized material, scratch resistance may be achieved at 1 N force without effect on electrical breakdown specification of 5.6 kV (AC peak).
The dielectrical constant εᵣ may range from 3 to 5. The capacitance value of the dielectric thermal interface structure sandwiched between two electrically conductive structures (carrier, heat dissipation body) may be in a range between 25 pF and 55 pF.
Compressibility of the thermal interface material may be between 1% to 20% (at maximal force of 18 N).
Package types which may be preferably equipped with the described thermal interface material are Transistor Outline (TO) packages, intelligent power modules (IPM), and all other modules with one or more packaged semiconductor chips.
The thermal interface material may have a comparative tracking index of 600 or more.
Creeping at a force of 1 N may be in a range of ±15% around 5.6%.

The thermal interface material may be provided on the package as a single layer (for instance by using an Al₂O₃ filled silicone with a specially adapted stiffness. Fine tuning of the desired material properties in terms of a specific application can be performed for instance by a special filler size distribution in combination with a special crosslinking density of the matrix polymer. As one important criterion for advantageous mechanical properties, a layer compressibility between 1% and 20% at ordinary mounting torque ratios (i.e. when connecting the package with a heat dissipation body by screwing a screw through the package and into the heat dissipation body) can be determined. Configuring the thermal interface structure as a single layer renders an additional adhesion layer or the like dispensable, since the intrinsic properties of the thermal interface structure may provide for an adhesion function as well.

According to a preferred embodiment of the invention, a thermal interface structure embodied as coating material may be placed on a copper surface of a chip carrier of the electronic component (such as a TO-package) with a defined softness of the coating layer. The mechanical properties (for instance stiffness) of the thermal interface layer can be described by:
Vickers hardness at or below 3 N/mm², in particular in a range of ±15% around HV 1 N/mm² (HM 10 N/mm²) at 1N measuring force.
Indention depth at 1N force of Vickers indentor not more than 50 μm, in particular not more than 30 μm (for instance at a total thickness of the thermal interface layer of at least 200 μm).
Young modulus in a range of ±15% around 0.6 GPa
Creeping at 1N force in a range of ±15% around 5.6%
Scratch resistance at 1N force without effect on electrical breakdown specification of 5.6 kV (AC peak)
Compressibility of layer in a range between 1% and 20%, preferably 10% (at a maximum force of 18 N, 0.1 MPa).

However, it has been determined by the present inventors that a decisive criterion as to whether a material is particularly appropriate as thermal interface structure for a package or an electronic component can be formulated as a combination of a high breakdown voltage per thickness of the interface material [kV/mm] with a high thermal conductivity [W/mK] of the thermal interface layer including a pronounced softness (indicated by the square of the Vickers hardness [N²/mm⁴]). These requirements may be specified by a physical unit, which may be denoted as MAME, and which should have a value of at least 1 kV W mm³ m⁻¹ K⁻¹ N⁻².

Corresponding definitions are:

Vbr=Breakthrough Voltage per thickness [kV/mm]

λ=Thermal conductivity [W/(mK)]

HV=Vickers hardness at 1N force [N/mm²]

MAME=(Vbr*λ)/HV² [1 kV W mm³ m⁻¹ K⁻¹ N⁻²]

It has turned out that when the value MAME is at least kV W mm³ m⁻¹ K⁻¹ N⁻², excellent results in terms of electrical (high breakdown voltage and thus reliable electric isolation), mechanical (sufficient softness to promote low thermal resistivity at interface between thermal interface structure and heat dissipation body) and thermal properties (high intrinsic thermal conductivity) can be achieved. When the value MAME is at least 3 kV W mm³ m⁻¹ K⁻¹ N⁻², outstanding results in terms of electrical, mechanical and thermal properties can be obtained.

These properties, as indicated by the physical parameter MAME, may be preferably combined with at least one of the following other layer characteristics:
thickness of the thermal interface structure of at least 200 μm, for instance 250 μm, (to obtain sufficient mechanical stability and scratch resistance)
electrical breakdown voltage of at least 10 kV/mm (AC peak) to ensure electrical stability even for power applications
comparative tracking index of at least 600
thermal conductivity of at least 2 W/mK (to ensure a sufficient amount of heat removal during operation of the electronic component)

With such a combination of material parameters, assembly of a one-layer substrate showing a high electrical isolation and at the same time low stiffness for proper surface wetting of the cooling unit is possible.

Such an embodiment of the invention enables the provision of TO-packages without the need of a conventional TIM or grease for mounting on a cooling unit by an assembly of the described thermal interface layer on the TO-package at the copper surface. Such a thermal interface layer or layer system combines high electrical isolation strength (electrical breakdown voltage above 5 kV) and high thermal conductivity (thermal resistivity below 0.5 K/W) with reliable contact area or wetting to a heat dissipation body such as a cooling unit.

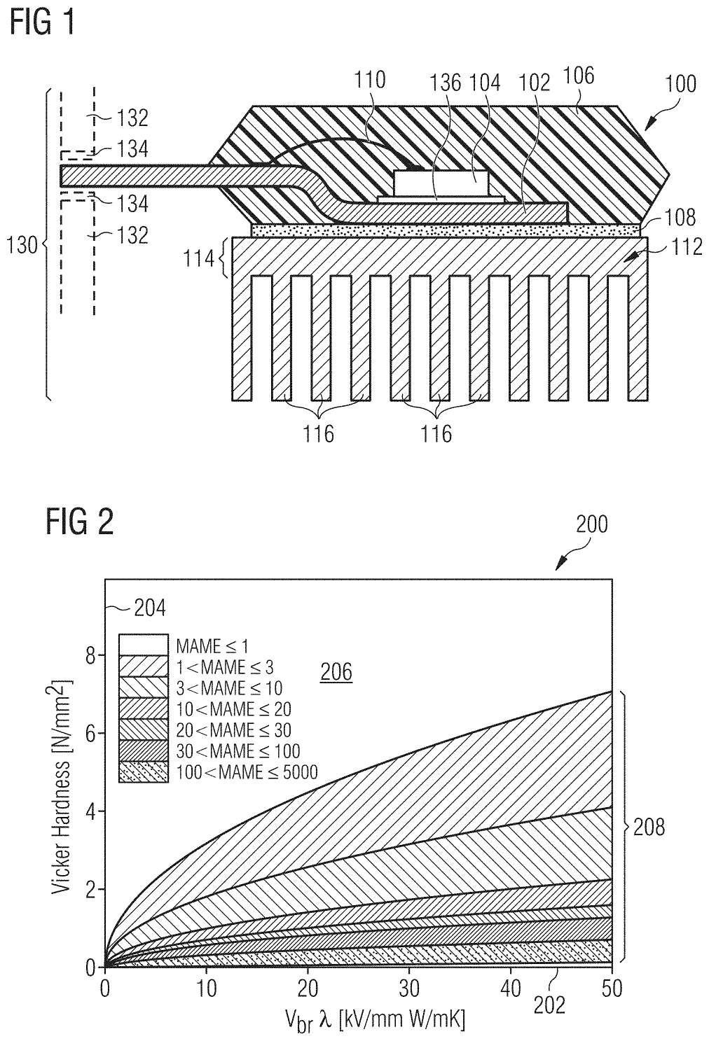

FIG. 1 illustrates a cross-sectional view of an electronic component 100, which is embodied as a Transistor Outline (TO) package, according to an exemplary embodiment of the invention. The electronic component 100 is mounted on a mounting structure 132, here embodied as printed circuit board, for establishing an arrangement 130 according to an exemplary embodiment of the invention.

The mounting structure 132 comprises an electric contact 134 embodied as a plating in a through hole of the mounting structure 132. When the electronic component 100 is mounted on the mounting structure 132, an electronic chip 104 of the electronic component 100 is electrically connected to the electric contact 134 via an electrically conductive carrier 102, here embodied as a leadframe made of copper, of the electronic component 100.

The electronic component 100 comprises the electrically conductive carrier 102, the electronic chip 104 (which is here embodied as a power semiconductor chip) adhesively (see reference numeral 136) mounted on the carrier 102, and an encapsulant 106 (here embodied as mold compound) encapsulating part of the carrier 102 and part of the electronic chip 104. As can be taken from FIG. 1, a pad on an upper main surface of the electronic chip 104 is electrically coupled to the carrier 102 via a bond wire 110.

During operation of the power package or electronic component 100, the power semiconductor chip in form of the electronic chip 104 generates a considerable amount of heat. At the same time, it must be ensured that any undesired current flow between a bottom surface of the electronic component 100 and an environment is reliably avoided.

For ensuring electrical insulation of the electronic chip 104 and removing heat from an interior of the electronic chip 104 towards an environment, an electrically insulating and thermally conductive interface structure 108 is provided which covers an exposed surface portion of the carrier 102 and a connected surface portion of the encapsulant 106 at the bottom of the electronic component 100. The electrically insulating property of the interface structure 108 prevents undesired current flow even in the presence of high voltages between an interior and an exterior of the electronic component 100. The thermally conductive property of the interface structure 108 promotes a removal of heat from the electronic chip 104, via the electrically conductive carrier 102 (of thermally properly conductive copper), through the interface structure 108 and towards a heat dissipation body 112. The heat dissipation body 112, which may be made of a highly thermally conductive material such as copper or aluminum, has a base body 114 directly connected to the interface structure 108 and has a plurality of cooling fins 116 extending from the base body 114 and in parallel to one another so as to remove the heat towards the environment. A mechanically soft and compressible property of the interface structure 108 ensures that when the heat dissipation body 112 is mounted on the electronic component 100 (for instance by a screw connection or by a clip, not shown), the interface between the interface structure 108 and the heat dissipation body 112 introduces only a small thermal resistance.

The foregoing description shows that the interface structure 108 fulfils a plurality of technical functions simultaneously and therefore requires certain mechanical, thermal and electrical properties at the same time. According to the described exemplary embodiments, the interface structure 108 is configured to fulfill all the above described technical functions simultaneously in a proper way when compressibility is in a range between 1% and 20%, in particular at or around 10%. Particularly advantageous effects can be achieved when a value of the breakdown voltage per thickness Vbr multiplied with the thermal conductivity A divided by the square of the Vickers hardness HV is more than 1 kV W mm³ m⁻¹ K⁻¹ N⁻² at room temperature (20° C.)

The interface structure 108 is configured to have an electric breakdown voltage of about 5.6 kV. This means that the electrical isolation of the interface structure 108 is maintained even when applying a voltage of 5.6 kV across the interface structure 108. In this context it is advantageous that the interface structure 108 has a quite small relative permittivity εᵣ of 4.5. A parasitic capacitance of the interface structure 108 (in combination with the electrically conductive material on both opposing main surfaces thereon) may be sufficiently low at around 40 pF. Thus, electric losses in high-frequency applications are acceptably low.

The value of the Vickers hardness of the material of the interface structure 108 can be preferably 1 N/mm². A maximum indention depth of a Vickers indentor at a measuring force of 1 N may be less than 50 μm so that it can be prevented that little scratches or indentations which may occur during ordinary use deteriorate the electric reliability of the electronic component 100. The interface structure 108 may have a Young modulus of 0.6 GPa. A correspondingly limited softness of the interface structure 108 ensures that any microprotrusions or microindentations at a connection surface of the heat removal body 112 to be filled with material of the interface structure 108 upon mounting which decreases a thermal resistance at the interface between the heat removal body 112 and the interface structure 108. Despite of the limited softness, the interface structure 108 shows a scratch resistance at a measuring force of 1 N without effect on the electrically breakdown specification of 5.6 kV. In other words, when a pyramid-shaped diamond indentor is pressed with 1 N against the surface of the interface structure 108 and is moved along this surface, small scratches which might be formed do not cause the electric breakdown voltage to fall below 5.6 kV, which still complies with the high demands of power applications.

The interface structure 108 may have an intrinsic thermal conductivity of for instance 2 W m⁻¹ K⁻¹ and is therefore capable of significantly contributing to the removal of heat generated during operation of the electronic component 100.

The mentioned physical parameters of the interface structure 108 may be accomplished by configuring it from a sufficiently soft polymer matrix (for instance of silicone) having embedded therein a certain amount of (for example 90 mass percent) filler particles (for instance from aluminum oxide) for promoting dielectric behaviour and/or thermal conductivity. One or more further additives may be added for fine-tuning the physical parameters of the interface structure 108. A further design parameter for adjusting the desired behaviour is the thickness of the interface structure 108 and the procedure of manufacturing and connecting it to the remainder of the electronic component 100.

Advantageously, the interface structure 108 consists of a single homogeneous layer of a thickness of 250 μm which is integrally formed with the carrier 102 and the encapsulant 106 by compression molding or transfer molding. Due to such a manufacturing, it is possible that material at the border between the interface structure 108 on the one hand and the carrier 102 and the encapsulant 106 on the other hand intermingles or mutually mixes to a certain extent to produce an electronic component 100 with a non-detachable interface structure 108. This further promotes the heat removal capability by reducing the thermal resistance at an interface between the carrier 102 and the interface structure 108 and at an interface between the encapsulant 106 and the interface structure 108. A further improvement of the heat removal capability of the interface structure 108 is obtained since the interface structure 108 extends over an entire bottom surface of the encapsulant 106 and over the entire exposed surface portion of the carrier 102 at a bottom of the electronic component 100. This is a consequence of the molding procedure used for manufacturing the interface structure 108. Integral formation of the interface structure 108 with the carrier 102 and the encapsulant 106 can be further promoted when the connection of the interface structure 108 to the carrier 102 and the encapsulant 106 is triggered by a chemical reaction such as a cross-linking of material of the interface structure 108 (which may be initiated by heat and/or pressure).

With the configuration of the thermal interface structure 108 according to FIG. 1, a proper trade-off between a sufficiently high electrical breakdown voltage, a sufficiently high capability of removing heat from the electronic chip 104 during operation of the electronic device 100 and a high robustness of the integral thermal interface structure 108 against undesired removal or scratching can be obtained.

Alternatively to the configuration shown in FIG. 1, it is also possible to attach the thermal interface structure 108 to the base body 112 of the heat dissipation body 114. Such a heat dissipation body 114 equipped with a thermal interface structure 108 may thereafter be connected to an exposed surface of a carrier 102 of an electronic component 100.

FIG. 2 illustrates a diagram 200 illustrating a dependence of Vickers hardness from a product of thermal conductivity λ and breakdown voltage per thickness Vbr of a material of an interface structure 108 of an electronic component 100 according to an exemplary embodiment of the invention. Different areas in diagram 200 relates to different values of the parameter MAME as calculated as the product of thermal conductivity λ and breakdown voltage per thickness Vbr divided by the square of the Vickers hardness.

The diagram 200 has an abscissa 202 and has an ordinate 204. Along the abscissa 202, the product of the electrical breakdown voltage per thickness Vbr and the thermal conductivity λ of the thermal interface material (see reference numeral 108 in FIG. 1) is plotted. The ordinate 204 shows the Vickers hardness (at a measuring force of 1 N). In a range 206, it may happen that inappropriate electrical, thermal and mechanical properties are obtained. However, within a range 208, sufficiently appropriate properties with regard to the above-mentioned thermal, mechanical and electrical criteria can be obtained. Thus, thermal interface materials according to exemplary embodiments of the invention may be taken from range 208 where the above-described parameter MAME has a value of larger than 1 kV W mm³ m⁻¹ K⁻¹ N⁻².

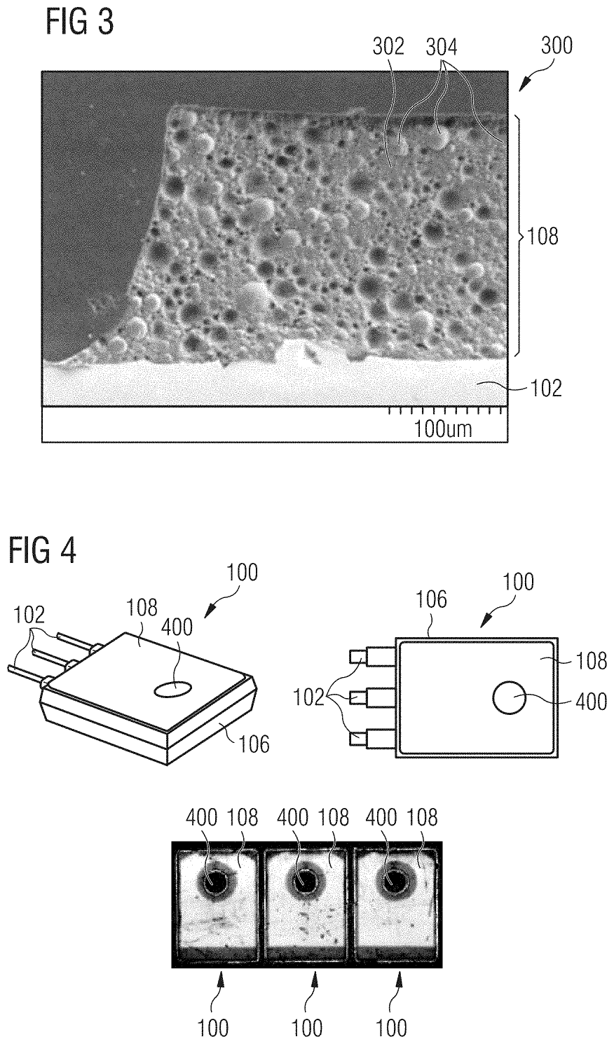

Referring to the lower surface of the interface structure 108 of FIG. 3 (which can form an interface to a carrier 102 such as a lead frame), proper adhesion properties are obtained by the formation of a material compound. This results in an advantageously low heat resistance. At the upper surface of the interface structure 108 of FIG. 3, a dry connection to a heat dissipation body 112 can be accomplished. The interface structure 108 may have a low thermal resistance on a metallic substrate and may have a high breakdown voltage on an electric insulator substrate.

FIG. 3 illustrates an SEM image 300 of aluminum oxide filled silicone as material for an interface structure 108 of an electronic component 100 according to an exemplary embodiment of the invention. As shown in FIG. 3, the interface structure 108 is arranged on a carrier 102 such as a lead frame (for instance made of copper).

Thus, the interface structure 108 comprises a matrix 302 of silicone filled with filler particles 304 of aluminum oxide. A mass percentage of the filler particles 304 may be 90%, whereas a mass percentage of the matrix 302 may be 10%. Thus, a relatively small volume is assumed by the silicone matrix 302 providing softness. In contrast to this, a relatively large volume is assumed by the freely selectable filler particles 304 which promote the thermal heat removal capability of the thermal interface material and strengthen the dielectric behaviour thereof.

Still referring to FIG. 3, a thermal resistivity of below 0.5 K/W (0.40 K/W, 0.37 K/W) could be measured for a TO-247 package with aluminum oxide filled silicone and without using thermal grease, which fulfills strict requirements of modern power packages. This can be compared with the thermal resistivity of conventional hard layer coating having a thermal resistivity of 0.5 K/W with thermal grease and 1.05 K/W without thermal grease. The cross-section of FIG. 3 shows no isolation, because only chip carrier and thermal interface material are visible, and no overlap on the first encapsulation will not lead to an isolation property.

FIG. 4 illustrates different views of electronic components 100 according to exemplary embodiments of the invention.

Firstly, FIG. 4 shows that the outline of the thermal interface structure 108 exactly corresponds to the outline of the corresponding main surface of the package or electronic component 100. A through-hole 400 extending through the entire electronic component 100 and therefore also through the thermal interface structure 108 allows to connect the electronic component 100 to a heat dissipation body 112 (not shown in FIG. 4) by a fastening element such as a screw (not shown in FIG. 4). In this context, the above-described softness of the material of the thermal interface structure 108 is advantageous, since it allows a certain compression of the material of the thermal interface structure 108 close to the fastening element during the fastening procedure, and therefore an equilibration of the fastening force and the prevention of undesired air gaps between an exterior surface of the thermal interface structure 108 on the one hand and material of the heat removal body 112 on the other hand.

Reliability tests for the shown electronic components 100 have proven the applicability of these packages. In particular, FIG. 4 shows three coated TO-247 packages after 96h stress indicating no delamination or voiding.

FIG. 5 illustrates a plan view of an electronic component 100 according to an exemplary embodiment of the invention having four galvanically insulated separate carrier regions 102A, 102B, 102C, and 102D. FIG. 5 therefore shows an embodiment having a split lead frame as carrier 102. In this embodiment, four separate and mutually electrically insulated electrically conductive lead frame islands are provided as the separate carrier regions 102A, 102B, 102C, and 102D. Each of the separate carrier regions 102A, 102B, 102C, and 102D is configured as a mounting base for a respective electronic chip(s) 104. On the backside of the electronic component 100, interface structure 108 is provided.

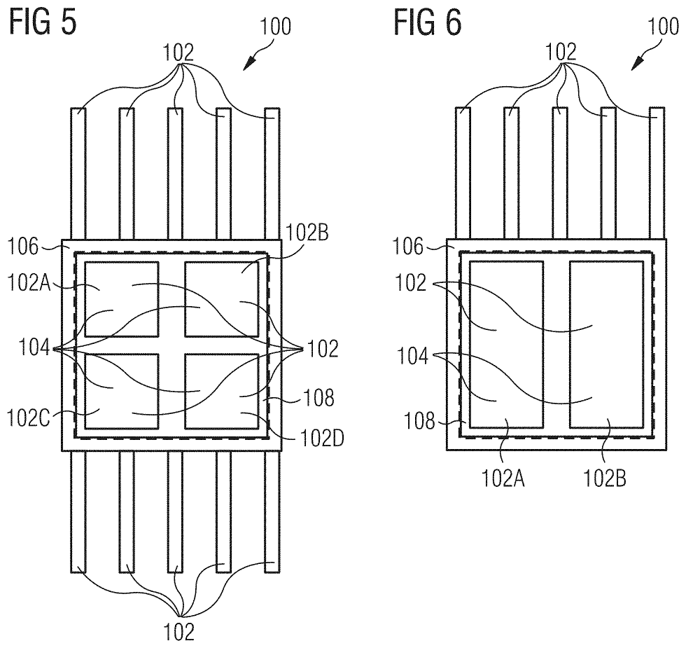

FIG. 6 illustrates a plan view of an electronic component 100 according to another exemplary embodiment of the invention having two galvanically insulated separate carrier regions 102A, 102B. The embodiment of FIG. 6 differs from the embodiment of FIG. 5 in that two rather than four lead frame islands are provided, so that two electronic chips 104 can be mounted on the separate carrier regions 102A, 102B according to FIG. 6. On the backside of the electronic component 100, interface structure 108 is provided.

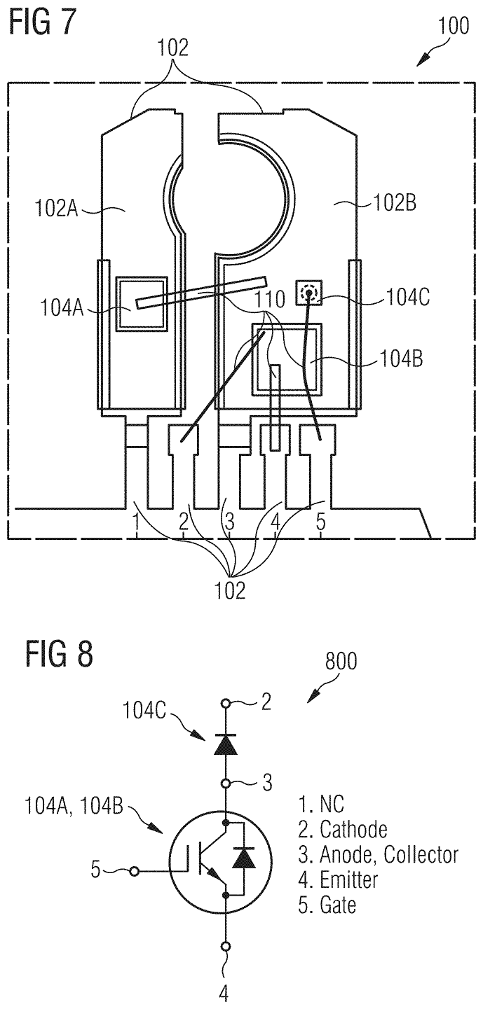

FIG. 7 illustrates a plan view of an electronic component 100 according to yet another exemplary embodiment of the invention having separate carrier regions 102A, 102B. Correspondingly, FIG. 8 illustrates a circuit diagram 800 illustrating the electronic functionality of the electronic component 100 according to FIG. 7. In the embodiment of FIG. 7 and FIG. 8, a first electronic chip 104A (which may be embodied as a boost diode) is mounted on carrier region 102A. A second electronic chip 104B (which may be embodied as a boost insulated gate bipolar transistor, IGBT) is mounted on carrier region 102B. A third electronic chip 104C (which may be embodied as an auxiliary diode) is mounted as well on carrier region 102B. Thus, the embodiment of FIG. 7 and FIG. 8 shows an electronic component 100 with a split lead frame having five pins (1, 2, 3, 4, 5) in an electronic application with a power factor correction.

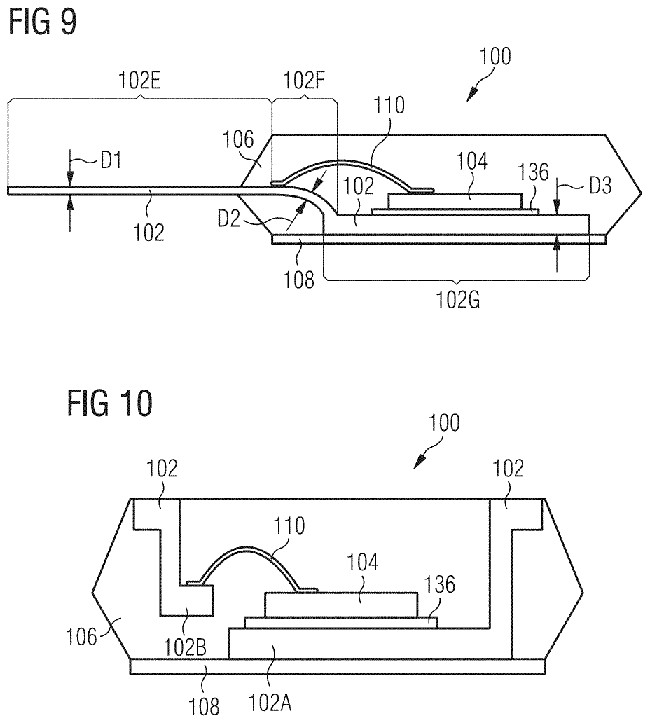

FIG. 9 illustrates a cross-sectional view of an electronic component 100 according to an exemplary embodiment of the invention having a carrier 102 with three different sections 102E, 102F, and 102G of different thicknesses D1<D2<D3 (alternatively, it is also possible that D1=D2). Thus, the embodiment of FIG. 9 relates to a variant with different thicknesses for the pin portion (see leads thickness D1) and for the actual chip carrier portion (see die pad thickness D3). The package according to FIG. 9 implements different thicknesses of pins (for instance D1=0.6 mm) and actual chip carrier (for instance D3=1.2 mm to 2 mm).

FIG. 10 illustrates a cross-sectional view of an electronic component 100 according to an exemplary embodiment of the invention having galvanically insulated separate carrier regions 102A, 102B. In the leadless embodiment of FIG. 10, the separate carrier regions 102A, 102B are electrically connected to one another by a bond wire 110. The leadless configuration according to FIG. 10 has electrically conductive contacts for soldering on a printed circuit board opposing to the isolation side.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

In the following, further aspects are described:

Aspect I: An electronic component, the electronic component comprising:
an electrically conductive carrier;
an electronic chip on the carrier;
an encapsulant encapsulating part of the carrier and the electronic chip;
an electrically insulating and thermally conductive interface structure, in particular covering an exposed surface portion of the carrier and a connected surface portion of the encapsulant;
wherein the interface structure is made of a material having a silicone matrix filled with filler particles, in particular filler particles comprising at least one of the group consisting of metal oxide, metal nitride, aluminum oxide, silicon oxide, boron nitride, zirconium oxide, silicon nitride, diamond, and aluminum nitride, with a mass percentage in a range between 75% and 98%, in particular in a range between 90% and 95%.
   Aspect II: An electronic component, the electronic component comprising:
an electrically conductive carrier which comprises a plurality of galvanically insulated separate carrier regions;
a plurality of electronic chips each of which being mounted on a respective one of the carrier regions;
an encapsulant encapsulating part of the carrier and the electronic chips;
a common electrically insulating and thermally conductive interface structure covering an exposed surface portion of the carrier regions and a connected surface portion of the encapsulant.
   Aspect III: The electronic component according to a previous Aspect, wherein the interface structure has a value of the breakdown voltage per thickness multiplied with the thermal conductivity divided by the square of the Vickers hardness of more than 1 kV W mm³ m⁻¹ K⁻¹ N⁻², in particular of more than 3 kV W mm³ m⁻¹ K⁻¹ N⁻², more particularly of more than 10 kV W mm³ m⁻¹ K⁻¹ N⁻².
   Aspect IV: A heat dissipation body, comprising:
a highly thermally conductive base body configured for dissipating heat;
an electrically insulating and thermally conductive interface structure attached to the base body and to be attached to an exposed surface portion of a chip carrier of an electronic component;
wherein the interface structure has a compressibility in a range between 1% and 20%, in particular in a range between 5% and 15%.
   Aspect V: A heat dissipation body, comprising:
a highly thermally conductive base body configured for dissipating heat;
an electrically insulating and thermally conductive interface structure attached to the base body and to be attached to an exposed surface portion of a chip carrier of an electronic component;
wherein the interface structure is made of a material having a silicone matrix filled with filler particles, in particular filler particles comprising at least one of the group consisting of metal oxide, metal nitride, aluminum oxide, silicon oxide, boron nitride, zirconium oxide, silicon nitride, diamond, and aluminum nitride, with a mass percentage in a range between 75% and 98%, in particular in a range between 90% and 95%.
   Aspect VI: A method of manufacturing an electronic component, the method comprising:
mounting an electronic chip on an electrically conductive carrier;
encapsulating part of the carrier and the electronic chip by an encapsulant;
forming an electrically insulating and thermally conductive interface structure, in particular to cover an exposed surface portion of the carrier and a connected surface portion of the encapsulant, having a compressibility in a range between 1% and 20%, in particular in a range between 5% and 15%.
   Aspect VII: A method of manufacturing an electronic component, the method comprising:
mounting an electronic chip on an electrically conductive carrier;
encapsulating part of the carrier and the electronic chip by an encapsulant;
forming an electrically insulating and thermally conductive interface structure, in particular to cover an exposed surface portion of the carrier and a connected surface portion of the encapsulant, wherein the interface structure is made of a material having a silicone matrix filled with filler particles, in particular filler particles comprising at least one of the group consisting of metal oxide, metal nitride, aluminum oxide, silicon oxide, boron nitride, zirconium oxide, silicon nitride, diamond, and aluminum nitride, with a mass percentage in a range between 75% and 98%, in particular in a range between 90% and 95%.
   Aspect VIII: A method of manufacturing an electronic component, the method comprising:
mounting each of a plurality of electronic chips on a respective one of a plurality of galvanically insulated separate carrier regions of an electrically conductive carrier;
encapsulating part of the carrier and the electronic chips by an encapsulant;
forming a common electrically insulating and thermally conductive interface structure covering an exposed surface portion of the carrier regions and a connected surface portion of the encapsulant.
   Aspect IX: The method according to Aspect VI, wherein the interface structure is formed by at least one of the group consisting of molding, in particular compression molding or transfer molding, stencil printing, and laminating.
   Aspect X: The method according to claim VI, wherein the interface structure is connected to the exposed surface portion of the carrier and to the connected surface portion of the encapsulant by chemically modifying the material of the interface structure, in particular by at least one of the group consisting of cross-linking and melting.
   Aspect XI: A method of using an interface material according to a previous Aspect for providing an electric isolation and a thermal coupling between a chip carrier of an electronic component and a heat dissipation body.
   Aspect XII: A method of using an electrically insulating and thermally conductive interface material for integration with an electronic component, wherein the interface material is made of a material having a silicone matrix filled with filler particles, in particular filler particles comprising at least one of the group consisting of metal oxide, metal nitride, aluminum oxide, silicon oxide, boron nitride, zirconium oxide, silicon nitride, diamond, and aluminum nitride, with a mass percentage in a range between 75% and 98%, in particular in a range between 90% and 95%, for providing an electric isolation and a thermal coupling between a chip carrier of the electronic component and a heat dissipation body.

What is claimed is:

1. An electronic component, the electronic component comprising:
an electrically conductive carrier;
an electronic chip on the carrier;
an encapsulant encapsulating part of the carrier and the electronic chip;
an electrically insulating and thermally conductive interface structure, in particular covering an exposed surface portion of the carrier and a connected surface portion of the encapsulant;
wherein the interface structure has a compressibility in a range between 1% and 20%, in particular in a range between 5% and 15%.

2. The electronic component according to claim 1, wherein the interface structure has a Vickers hardness in a range between 0.50 N/mm² and 3 N/mm², in particular in a range between 0.85 N/mm² and 1.50 N/mm², at a measuring force of 1 N.

3. The electronic component according to claim 1, wherein the interface structure has a Young modulus in a range between 0.1 GPa and 2 GPa, in particular in a range between 0.3 GPa and 1.5 GPa.

4. The electronic component according to claim 1, comprising at least one of the following features:
the interface structure shows a scratch resistance at a measuring force of 1 N without effect on an electrical breakdown voltage of at least 5.6 kV;
the interface structure shows a scratch resistance at a measuring force of 1 N without effect on an electrical breakdown voltage per thickness of at least 10 kV/mm.

5. The electronic component according to claim 1, wherein the interface structure has a thickness in a range between 50 μm and 600 μm, in particular in a range 100 μm and 400 μm.

6. The electronic component according to claim 1, comprising at least one of the following features:
the interface structure has an electric breakdown voltage of at least 2 kV, in particular of at least 5 kV, more particularly in a range between 5 kV and 12 kV;
the interface structure has an electric breakdown voltage per thickness of at least 5 kV/mm, in particular of at least 10 kV/mm, more particularly of at least 15 kV/mm.

7. The electronic component according to claim 1, wherein the interface structure has a thermal conductivity of at least 1 W m⁻¹ K⁻¹, in particular of at least 2 W m⁻¹ K⁻¹, more particularly in a range between 3 W m⁻¹ K⁻¹ and 20 W m⁻¹ K⁻¹.

8. The electronic component according to claim 1, wherein the interface structure comprises or consists of a soft polymer matrix filled with filler particles.

9. The electronic component according to claim 1, wherein the interface structure in combination with the carrier and a heat dissipation body to be attached to an external surface of the interface structure has a capacitance in a range between 10 pF and 100 pF, in particular in a range between 25 pF and 55 pF.

10. The electronic component according to claim 1, wherein the interface structure, the covered exposed surface portion of the carrier and the connected surface portion of the encapsulant are integrally formed with one another, in particular so that the interface structure is not detachable from a remainder of the electronic component.

11. The electronic component according to claim 1, wherein material of the interface structure is intermingled with material of the covered exposed surface portion of the carrier and material of the connected surface portion of the encapsulant.

12. The electronic component according to claim 1, wherein the interface structure extends over an entire bottom surface of the encapsulant and over the entire exposed surface portion of the carrier at a bottom of the electronic component.

13. The electronic component according to claim 1, wherein the interface structure has a relative permittivity in a range between 1.5 and 6, in particular in a range between 4 and 5.

14. The electronic component according to claim 1, wherein the carrier comprises a plurality of galvanically insulated separate carrier regions.

15. The electronic component according to claim 1, wherein the carrier comprises a plurality of sections of different thicknesses.

16. The electronic component according to claim 1, wherein the electrically insulating and thermally conductive interface structure is configured to be attached at an external surface to a heat dissipation body.

17. An arrangement, the arrangement comprising:
a mounting structure comprising an electric contact;
an electronic component according to claim 1 mounted on the mounting structure so that the electronic chip is electrically connected to the electric contact.

18. An electrically insulating and thermally conductive interface material for integration with an electronic component, wherein the interface material has a compressibility in a range between 1% and 20%, in particular in a range between 5% and 15%.
